(19) United States
(12) Patent Application Publication
(10) Pub. No.: US 2026/0181967 A1
(43) Pub. Date: Jun. 25, 2026

(54) VERTICAL JUNCTION FIELD EFFECT TRANSISTOR AND MANUFACTURING METHOD THEREOF

(71) Applicant: Richtek Technology Corporation, Zhubei City (TW)

(72) Inventors: Wu-Te Weng, Hsinchu (TW); Yi-Rong Tu, Taipei (TW); Ying-Shiou Lin, Chiayi (TW); Han-Chung Tai, Hsinchu (TW); Chih-Feng Huang, Hsinchu (TW); Yong-Zhong Hu, Hsinchu (TW)

(21) Appl. No.: 19/008,745

(22) Filed: Jan. 3, 2025

(30) Foreign Application Priority Data
Dec. 20, 2024 (TW) 113149810

(51) Int. Cl. H10D 30/83; H10D 30/01

(52) U.S. Cl. CPC H10D 30/831; H10D 30/0515

(57) ABSTRACT

The present invention provides a vertical junction field-effect transistor (JFET) and manufacturing method thereof. The vertical JFET includes an N+ type substrate, an N type bulk region, an N type drift region, two P type buried regions, two P type base regions, two P+ type gate regions, and an N+ type source region. A vertical channel is formed between the N+ type source region and the N+ type substrate, allowing conduction of current exclusively in the vertical direction. The continuous P type regions formed by the P type buried and base regions improve the JFET's conductive resistance, breakdown voltage, and leakage current characteristics.

### CROSS REFERENCE

The present invention claims priority to TW 113149810 filed on Dec. 20, 2024.

### BACKGROUND OF THE INVENTION

### Field of Invention

The present invention relates to a vertical junction field-effect transistor (JFET) and a manufacturing method thereof. In particular, it relates to such a vertical JFET and a manufacturing method thereof, which improves conduction resistance, breakdown voltage, and leakage current characteristics.

### Description of Related Art

As shown in FIG. 1, a vertical junction field-effect transistor (Vertical JFET) 10 is a semiconductor device that controls channel conductivity using an electric field. Its distinctive feature lies in the vertical direction of current conduction through the channel, perpendicular to the substrate.

The vertical JFET 10 comprises a drain 18 located at the bottom of the device, typically made of heavily doped N+ type semiconductor material to support current conduction. Above the drain 18 is the N type region 12, which serves as a lightly doped N type semiconductor layer that supports high voltage and assists vertical current conduction. Adjacent to and above the N type region 12 are P+ type gate regions 16, which consist of P type regions positioned on either side of the channel. By applying a voltage to the gate regions, the channel can be opened or closed, thereby regulating current flow. The channel forms the current path between the N+ type source 17, located at the top of the device, and the drain 18. Current conduction through the channel can occur in both vertical and horizontal directions, but the vertical JFET 10 is optimized for vertical conduction, with the N+type source 17 serving as the starting point for current flow.

The operation of the vertical JFET 10 is based on the depletion region effect. When a reverse bias is applied between the P+ type gate region 16 and the N type region 12, the depletion region expands, blocking current flow. Conversely, when an appropriate voltage is applied to the P+ type gate region 16, the channel opens, allowing current to flow between the N+ type source 17 and the drain 18 through the channel. The conductivity of the channel is determined by the gate voltage, enabling precise control of the current.

However, conventional vertical JFETs 10 exhibit significant design limitations in optimizing performance. A key issue lies in the inability to effectively balance doping concentrations across different regions, thereby simultaneously optimizing the electric field distribution and reducing conduction resistance.

From a reliability perspective, the N type region 12 in prior art devices often has a relatively high doping concentration, which reduces the depletion region width. This structural characteristic limits the uniform distribution of the electric field within the N type region 12, resulting in excessive field concentration in localized areas, thereby reducing the breakdown voltage of the device. Consequently, this design impacts the voltage withstand capability and limits the reliability of the device in high-voltage applications.

From a conduction resistance perspective, the prior art N type region 12 often has a relatively low doping concentration, failing to provide sufficiently low resistance to enhance the conduction path of the P+ type gate region 16. During operation in the conduction state, high base region resistance increases the resistance loss between the N+ type source region 17 and the drain 18, further degrading conduction efficiency. Additionally, an excessively low doping concentration in the N type region 12 may lead to insufficient electrical connection between the source 17 and the drain 18, weakening effective current control in the channel.

In view of the aforementioned issues, the present invention provides a vertical JFET and manufacturing method thereof that significantly improve conduction resistance, breakdown voltage, and leakage current characteristics through a simplified manufacturing process.

### SUMMARY OF THE INVENTION

From one perspective, the present invention provides a vertical junction field-effect transistor (JFET), comprising: an N+ type substrate, formed of a semiconductor material; an N type bulk region, formed on and connected to the N+ type substrate; an N type drift region, formed on and connected to the N type bulk region; two P type buried regions, formed beneath the N type drift region, horizontally separated from each other without connection, located on the left and right sides of the N type drift region, and spaced apart by a portion of the N type bulk region; two P type base regions, formed on and connected to the corresponding P type buried regions; two P+ type gate regions, electrically connected to the corresponding P type base regions and further connected to the P type buried regions through the corresponding P type base regions; and an N+ type source region, formed within the N type drift region; wherein, during the conductive operation of the vertical JFET, a channel is exclusively formed in the vertical direction between the N+ type source region and the N+ type substrate through the N type drift region and the N type bulk region, allowing a conduction current to flow; wherein the structure of the vertical JFET ensures that the channel is exclusively formed in the vertical direction, and the conduction current flows vertically from the N+ type source region to the N+ type substrate; wherein the two P type buried regions are connected to the corresponding two P type base regions, forming two independent and continuous P type regions; wherein the two P type regions improve the conduction resistance, breakdown voltage, and leakage current characteristics of the vertical JFET.

In one embodiment, the semiconductor material is silicon (Si), silicon carbide (SiC), or gallium nitride (GaN).

In one embodiment, the N type drift region is formed by an epitaxial growth process or an ion implantation process.

In one embodiment, the horizontal extension of the two P type buried regions relative to the corresponding two P type base regions includes: (a) extending beyond the sides of the corresponding two P type base regions to cover and connect to a portion of the lower surface of the N type drift region; or (b) not extending beyond the sides of the corresponding two P type base regions and not covering the lower surface of the N type drift region.

In one embodiment, the structure of the vertical JFET includes: (a) a planar structure, wherein the upper surface of the N type drift region and the upper surfaces of the two P type base regions lie on the same vertical height of a horizontal plane, and the two gates form ohmic contacts with the corresponding two P+ type gate regions, fully located on the horizontal plane; or (b) a trench structure, wherein the upper surface of the N type drift region and the upper surfaces of the two P type base regions lie on the same vertical height of a horizontal plane, and at least portions of the two P+ type gate regions are located below the horizontal plane within the bottoms and interior sidewalls of the corresponding two trenches, which extend downward from the horizontal plane into the interiors of the two P type buried regions.

In one embodiment, the two P type regions and the N type drift region form a super junction.

In one embodiment, the doping concentration of the two P type base regions is higher than that of the two P type buried regions to reduce the resistance between the two P+ type gate regions and the corresponding two P type buried regions, while the doping concentration of the two P type buried regions is relatively lower to increase the breakdown voltage.

In one embodiment, the vertical JFET further includes two gates respectively connected to the corresponding two P+ type gate regions, and the two gates form ohmic contacts with the corresponding two P+ type gate regions, wherein the material of the two gates is titanium nitride (TiN), tantalum nitride (TaN), or aluminum (Al).

In one embodiment, the N type drift region is formed by an ion implantation process using implantation elements such as nitrogen (N), phosphorus (P), arsenic (As), antimony (Sb), or bismuth (Bi).

In one embodiment, the two P type buried regions and the two P type base regions are respectively formed by corresponding ion implantation processes using implantation elements such as boron (B), aluminum (Al), gallium (Ga), or indium (In).

From another perspective, the present invention provides a manufacturing method for a vertical junction field-effect transistor (JFET), comprising: providing an N+ type substrate, which is a semiconductor material; forming an N type bulk region on and connected to the N+ type substrate; forming an N type drift region on and connected to the N type bulk region; forming two P type buried regions and two P type base regions; forming two P+ type gate regions by an ion implantation process, wherein the two P+ type gate regions are connected to the corresponding two P type base regions; and forming an N+ type source region within the N type drift region by an ion implantation process; wherein the two P type buried regions are located beneath the N type drift region, horizontally separated from each other, and not connected, located on the left and right sides of the N type drift region, and spaced apart by a portion of the N type bulk region; wherein the two P type base regions are located on and connected to the corresponding two P type buried regions; wherein the two P+ type gate regions are electrically connected to the corresponding two P type buried regions via the two P type base regions; wherein, during the conductive operation of the vertical JFET, a channel is exclusively formed in the vertical direction between the N+ type source region and the N+ type substrate via the N type drift region and the N type bulk region, allowing a conduction current to flow; wherein the structure of the vertical JFET ensures that the channel is exclusively formed in the vertical direction, and the conduction current flows vertically from the N+ type source region to the N+ type substrate; wherein the two P type buried regions are connected to the corresponding two P type base regions to form two independent and continuous P type regions, which improve the conduction resistance, breakdown voltage, and leakage current characteristics of the vertical JFET.

In one embodiment, the structure of the vertical JFET includes a planar structure. The step of forming the two P type buried regions and the two P type base regions includes: forming the two P type buried regions beneath the N type drift region by an ion implantation process; and forming the two P type base regions on the corresponding two P type buried regions by an ion implantation process; wherein the N type bulk region is formed by an epitaxial process, and wherein the upper surface of the N type drift region and the upper surfaces of the two P type base regions lie on the same vertical height of a horizontal plane, and are respectively electrically connected to the two P+ type gate regions via ohmic contacts on two gates positioned entirely on the horizontal plane.

In one embodiment, the structure of the vertical JFET includes a trench structure. The step of forming the two P type buried regions and the two P type base regions includes: forming two P type implantation regions beneath the N type drift region by an ion implantation process; etching downward from an upper surface into the two P type implantation regions to form two trenches and the two P type buried regions by an etching process; and forming the two P type base regions on the corresponding two P type buried regions by an ion implantation process. The step of forming the two P+ type gate regions connected to the corresponding two P type base regions includes: implanting P type impurities into the bottom and interior sidewalls of the two trenches by an ion implantation process to form the two P+ type gate regions. The N type bulk region is formed by an epitaxial process, and the upper surface of the N type drift region and the upper surfaces of the two P type base regions lie on the same vertical height of a horizontal plane, with portions of the two P+ type gate regions located beneath the bottom surfaces and interior sidewalls of the two trenches below the horizontal plane.

In one embodiment, the structure of the vertical JFET includes a super junction structure. The step of forming the two P type buried regions and the two P type base regions includes: forming two P type implantation regions beneath the N type drift region by an ion implantation process; etching downward from an upper surface into the two P type implantation regions to form two trenches and the two P type buried regions by an etching process; implanting P type impurities into the bottom and interior sidewalls of the two trenches by an ion implantation process to form the two P type base regions; and filling the two trenches with two P type pillars. The two P type regions and the N type drift region form a super junction.

Compared to prior art, the present invention provides significant advantages. The design of the vertical JFET in the present invention optimizes device performance through the doping concentration of the P type buried regions and P type base regions, yielding several benefits.

First, the present invention employs lower doping concentrations for the P type buried regions, formed beneath the N type drift region. This design enables uniform electric field distribution and depletion region formation in the N type drift region during the conduction mode, improving control precision of the current channel and reducing the risk of localized high electric fields. Such a structure not only enhances breakdown voltage but also provides higher stability and reliability in high-voltage applications.

On the other hand, the present invention employs higher doping concentrations for the P type base regions to effectively reduce the resistance within the base regions. As the P type base regions are located above the P type buried regions and electrically connect the P+ type gate regions to the P type buried regions in the vertical direction, the low-resistance design of the base regions significantly reduces current losses during the conduction state. This characteristic notably improves conduction efficiency, reduces power losses, and enhances device performance under high-power operation. Additionally, the high doping concentration of the P type base regions strengthens electrical connection stability with the P type buried regions, thereby providing more precise channel control and improved dynamic response characteristics.

In summary, the present invention achieves comprehensive performance optimization through rational distribution of the doping concentrations of the P type buried regions and P type base regions. The low doping concentration of the P type buried regions ensures uniform electric field distribution within the N type drift region, improving control in conduction mode, breakdown voltage, and reliability. The high doping concentration of the P type base regions significantly reduces conduction resistance, enhances conduction efficiency, and improves overall device performance. Such advancements enable the vertical JFET of the present invention to exhibit superior performance in high-voltage and high-power applications, overcoming the deficiencies of prior art and establishing itself as an important innovation in high-performance electronic components.

The objectives, technical details, features, and effects of the present invention will be better understood with regard to the detailed description of the embodiments below, with reference to the attached drawings.

### BRIEF DESCRIPTION OF THE DRAWINGS

FIG. 1 is a cross-sectional schematic diagram illustrating an prior art structure of a vertical junction field-effect transistor (JFET).

FIG. 2A is a cross-sectional schematic diagram illustrating a vertical JFET according to an embodiment of the present invention.

FIG. 2B is another cross-sectional schematic diagram illustrating a vertical JFET according to an embodiment of the present invention.

FIG. 3 is a cross-sectional schematic diagram illustrating another type of vertical JFET according to an embodiment of the present invention.

FIG. 4 is a cross-sectional schematic diagram illustrating yet another type of vertical JFET according to an embodiment of the present invention.

FIGS. 5A-5F are cross-sectional schematic diagrams illustrating the manufacturing method of a vertical JFET 20 according to an embodiment of the present invention.

FIGS. 6A-6F are cross-sectional schematic diagrams illustrating the manufacturing method of a vertical JFET 30 according to another embodiment of the present invention.

FIGS. 7A-7F are cross-sectional schematic diagrams illustrating the manufacturing method of a vertical JFET 40 according to yet another embodiment of the present invention.

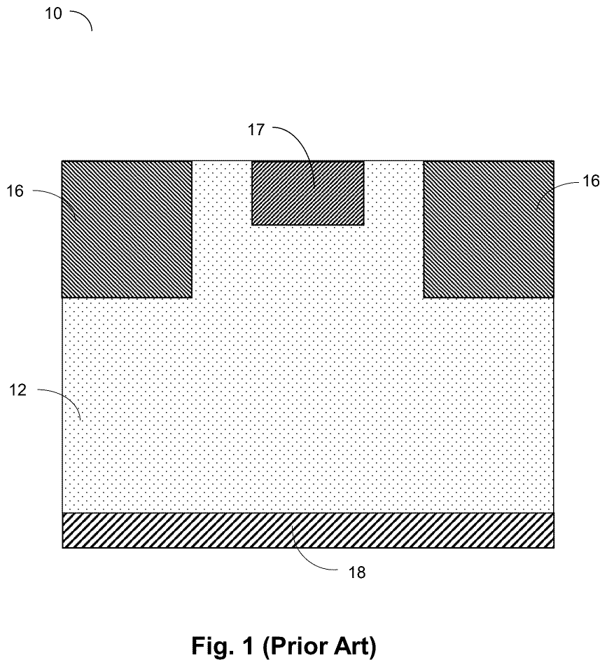

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

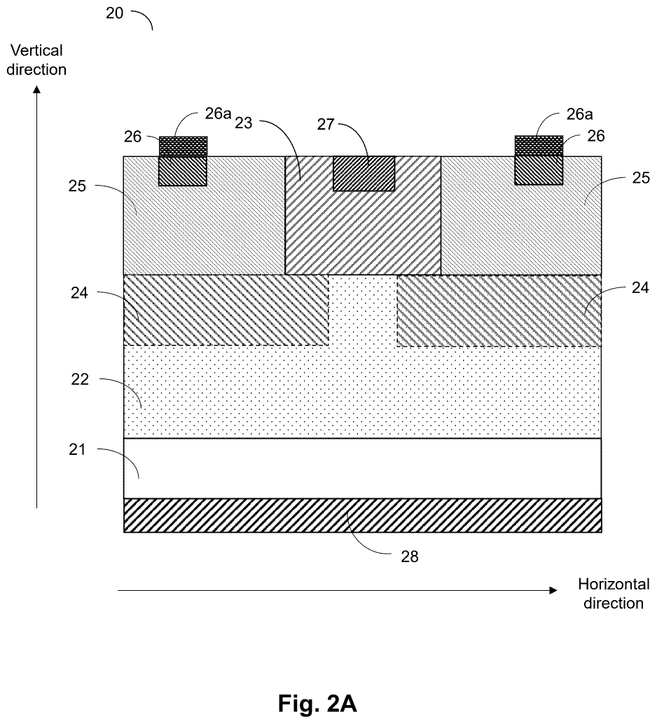

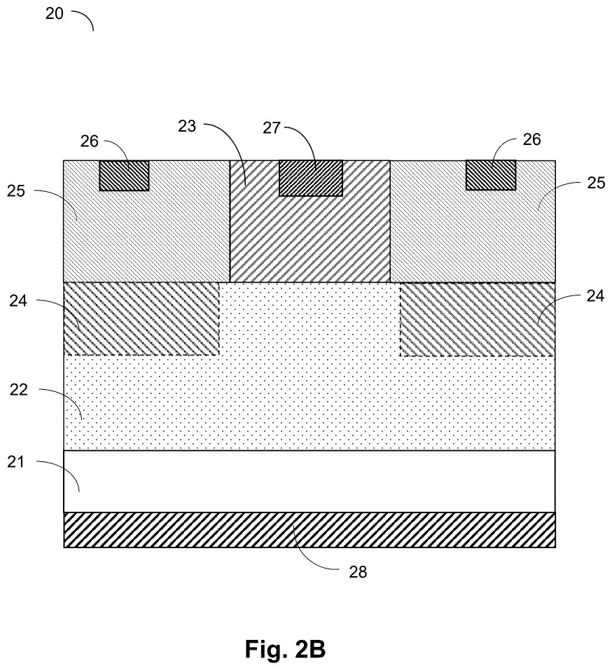

FIG. 2A illustrates a cross-sectional schematic diagram of a vertical junction field-effect transistor (JFET) 20 designed for efficient vertical current conduction. The vertical JFET 20 comprises an N+ type substrate 21, an N type bulk region 22, an N type drift region 23, two P type buried regions 24, two P type base regions 25, two P+ type gate regions 26, two gates 26a, an N+ type source region 27, and an N+ type drain region 28.

The N+ type substrate 21 is a heavily doped N-type semiconductor layer, partially forming the drain region 28. The N type bulk region 22 is formed above and connected to the N+ type substrate 21 as a lightly doped N-type semiconductor layer. Its primary function is to enhance the uniformity of the electric field distribution, thereby improving breakdown voltage. The N type drift region 23, further formed above the N type bulk region 22, also consists of lightly doped N-type material. This region is the core of the device, enabling vertical current conduction and supporting high-voltage operation.

In one embodiment, the N+ type substrate 21 is made of semiconductor material such as silicon (Si), silicon carbide (SiC), or gallium nitride (GaN). In a preferred embodiment, the semiconductor material is silicon carbide.

In one embodiment, the N type drift region 23 is formed by an epitaxial growth process or an ion implantation process.

In one embodiment, the P type base regions 25 have a higher doping concentration compared to the P type buried regions 24, reducing the resistance between the P+ type gate regions 26 and the P type buried regions 24. The P type buried regions 24, in contrast, have a lower doping concentration to enhance breakdown voltage.

In one embodiment, the N type drift region 23 is formed by ion implantation using elements such as nitrogen (N), phosphorus (P), arsenic (As), antimony (Sb), or bismuth (Bi).

In one embodiment, the P type buried regions 24 and the P type base regions 25 are respectively formed by ion implantation using elements such as boron (B), aluminum (Al), gallium (Ga), or indium (In).

The two P type buried regions 24 are formed beneath the N type drift region 23, separated horizontally without connection. They are positioned on the left and right sides of the N type drift region 23, with the N type bulk region 22 separating them. The P type buried regions 24, having a lower doping concentration relative to the P type base regions 25, regulate the electric field distribution, ensuring uniformity in the N type drift region 23. This design enhances the breakdown voltage of the vertical JFET 20. The P type base regions 25, formed above and connected to the corresponding P type buried regions 24, have higher doping concentrations to significantly reduce resistance, improving current conduction efficiency. Each P type buried region 24 and its corresponding P type base region 25 form a continuous P type region, stabilizing the overall structure and further improving the conduction resistance, breakdown voltage, and leakage current characteristics of the vertical JFET 20.

The two P+ type gate regions 26 are embedded in the corresponding P type base regions 25 and electrically connected to the P type buried regions 24 through the P type base regions 25. The P+ type gate regions 26 enable the opening and closing of the vertical channel by applying a control voltage. The gates 26a, in ohmic contact with the P+ type gate regions 26, provide stable field control. The gate materials may include titanium nitride (TiN), tantalum nitride (TaN), or aluminum (Al). The N+ type source region 27 is located at the top of the N type drift region 23, serving as the primary current input terminal. It forms a vertical channel with the N+ type substrate 21 to achieve efficient current conduction.

In the conductive state, a vertical channel is formed between the N+ type source region 27 and the N+ type substrate 21 via the N type drift region 23 and the N type bulk region 22. The conduction current flows vertically from the N+ type source region 27 to the N+ type substrate 21. This vertical structure ensures directional channel formation, avoiding lateral channels and significantly enhancing conduction efficiency while reducing power loss. The optimized structure of the P type buried regions 24 and P type base regions 25 further improves electric field uniformity and low-resistance characteristics, which are crucial for high-voltage applications.

The structure of the vertical JFET according to the present invention allows for various design variations, such as planar and trench structures. In the planar structure, the upper surface of the N type drift region 23 aligns with the upper surfaces of the P type base regions 25 at the same vertical height, with the gates 26a making ohmic contact with the P+ type gate regions 26. In the trench structure, the upper surfaces of the N type drift region 23 and the P type base regions 25 align at the same vertical height, with portions of the P+ type gate regions 26 positioned below the same horizontal plane in corresponding trenches. These trenches extend downward into the P type buried regions 24, as detailed below. These design variations offer flexibility for different applications, further expanding the utility of the device.

Overall, the vertical JFET 20 achieves significant performance improvements through carefully designed multi-layer structures and doping concentration distributions. It offers advantages in conduction resistance, breakdown voltage, and leakage current control, providing an efficient and reliable solution for high-voltage and high-power electronic applications.

FIG. 2B shows another embodiment of the vertical JFET 20. The difference between the embodiment in FIG. 2B and that in FIG. 2A lies in the extension design of the P type buried regions 24 relative to the P type base regions 25. In FIG. 2A, each P type buried region 24 extends horizontally beyond the sides of the corresponding P type base region 25, covering and connecting to portions of the lower surface of the N type drift region 23. This design enhances electric field control between the P type buried regions 24 and the N type drift region 23, improving breakdown voltage and current control characteristics.

However, in the embodiment shown in FIG. 2B, the P type buried regions 24 do not extend horizontally beyond the sides of the P type base regions 25 and do not cover the lower surface of the N type drift region 23. This design reduces the influence of the P type buried regions 24 on the lower surface of the N type drift region 23, resulting in lower conduction resistance. It is better suited for specific applications requiring simpler electric field distribution and may reduce manufacturing complexity.

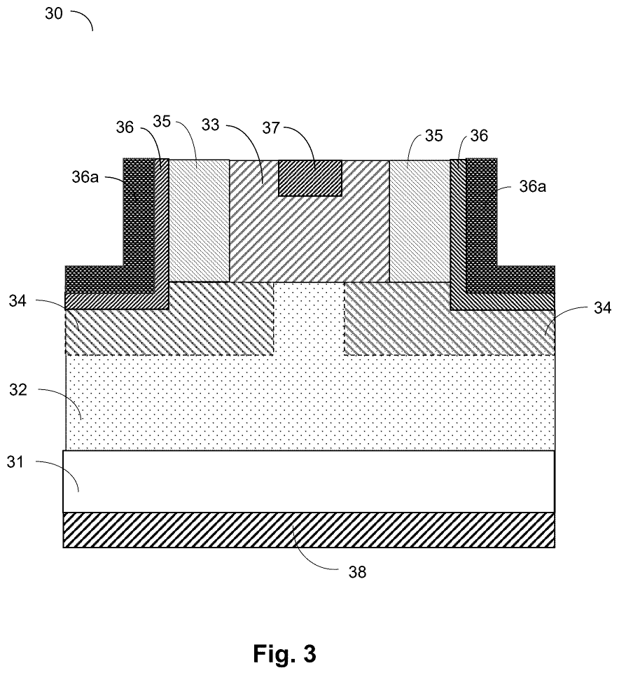

FIG. 3 illustrates a cross-sectional schematic diagram of another embodiment of a vertical junction field-effect transistor (JFET) 30 with a trench structure. This structure features two vertical trenches to further enhance device performance and control capabilities. The vertical JFET 30 comprises an N+ type substrate 31, an N type bulk region 32, an N type drift region 33, two P type buried regions 34, two P type base regions 35, two P+ type gate regions 36, an N+ type source region 37, a drain 38, and gates 36a.

In the structure shown in FIG. 3, the N+ type substrate 31 serves as the main current outlet and constitutes the drain region 38. The N type bulk region 32, located directly above the N+ type substrate 31, enhances the uniformity of the electric field distribution, thereby improving breakdown voltage. The N type drift region 33 is situated above the N type bulk region 32 and provides the primary vertical current conduction path.

The two P type buried regions 34 are formed beneath the N type drift region 33, separated horizontally without connection. They are positioned on the left and right sides of the N type drift region 33, with the N type bulk region 32 separating them. These P type buried regions 34 are designed to regulate the electric field distribution and improve breakdown voltage. The two P type base regions 35 are located above the corresponding P type buried regions 34, and their higher doping concentrations reduce resistance, further enhancing conduction efficiency. The P+ type gate regions 36 are embedded in the corresponding trenches, extending through the trench sidewalls into the device interior. They connect to the corresponding P type base regions 35 and, through these, or directly, to the P type buried regions 34.

The trench structure of the vertical JFET 30, as shown in FIG. 3, is characterized by the placement of the two P+ type gate regions 36 within corresponding trenches. This trench design primarily shortens the electric field control channel length, enhances the control capabilities of the gates 36a, and minimizes lateral current formation. Additionally, the P+ type gate regions 36 within the trenches form ohmic contact with the gates 36a, enabling vertical channel opening and closing by applying a control voltage.

The N+ type source region 37 is located at the top of the N type drift region 33, serving as the primary current input terminal. When the vertical JFET 30 is in the conductive state, a vertical channel is formed between the N+ type source region 37 and the N+ type substrate 31 through the N type drift region 33 and the N type bulk region 32. The conduction current flows vertically from the N+ type source region 37 to the N+ type substrate 31. This structure ensures channel directionality, avoiding lateral current formation, thereby enhancing conduction efficiency and reducing power loss.

Furthermore, the trench structure provides design flexibility. For example, the position of the P type base regions 35 within the trenches and the depth of the P+ type gate regions 36 can be adjusted based on application requirements to optimize conduction resistance, breakdown voltage, and leakage current control performance. By adopting this design, the vertical JFET 30 demonstrates superior performance in high-voltage and high-power applications, particularly in scenarios requiring strong electric field control.

The remaining parts of the vertical JFET 30, including the N+ type substrate 31, N type bulk region 32, N type drift region 33, P type buried regions 34, P type base regions 35, drain 38, and gates 36a, are structurally and functionally similar to the corresponding parts of the vertical JFET 20. For details, refer to the description of the vertical JFET 20.

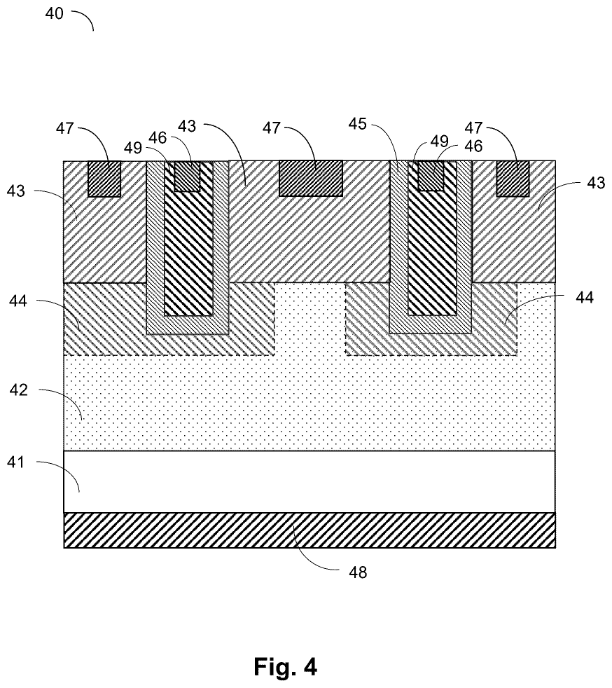

FIG. 4 shows a cross-sectional schematic diagram of a vertical JFET 40 with a super junction structure. The vertical JFET 40 includes an N+ type substrate 41, which serves as the base semiconductor material. An N type bulk region 42 is formed above the N+ type substrate 41 to support the upper structure. Located above the N type bulk region 42 is the N type drift region 43, which provides the main current conduction channel. Beneath the N type drift region 43 are two P type buried regions 44, positioned on either side of the N type drift region 43 and separated horizontally without contact.

Above each P type buried region 44 is a P type base region 45, forming corresponding P type regions. Through an ion implantation process, P+ type gate regions 46 are further formed and embedded within corresponding P type columns 49. These P+ type gate regions 46 are electrically connected to the corresponding P type base regions 45 and P type buried regions 44 through the P type columns 49, providing excellent gate control capabilities. Within the N type drift region 43 is an N+ type source region 47, serving as the source terminal for current conduction. Current flows from the N+ type source region 47 through the N type drift region 43 and N type bulk region 42 to the N+ type substrate 41, which is connected to the drain 48.

FIG. 4 illustrates that the P type buried regions 44 extend upward to form two trench structures, filled with P type columns 49. These P type columns 49 connect to the P type base regions 45, further enhancing the super junction structure performance of the vertical JFET 40. The core of the super junction structure lies in the doping concentration design between the P type buried regions 44, P type columns 49, and the N type drift region 43. By alternating the P type and N type regions, a uniform electric field distribution is achieved. This uniform distribution significantly improves the breakdown voltage of the vertical JFET 40 while reducing conduction resistance, thereby enhancing the overall performance of the device.

Furthermore, the super junction structure illustrated in FIG. 4 reduces leakage current by optimizing the formation of depletion regions through the vertical arrangement of P-type regions. This configuration suppresses lateral leakage current, making it particularly suitable for high-voltage applications such as power conversion and power management circuits, delivering excellent performance and reliability.

In a preferred embodiment, the doping concentration between the P-type regions and multiple N-type drift regions 43 is designed to ensure uniform electric field distribution within the super junction when the vertical JFET 40 is in conduction mode, thereby enhancing the breakdown voltage. The doping concentration of the P-type buried regions 44 is designed to be lower than that of the P-type base regions 45, reducing parasitic currents within the super junction. The N-type drift region 43 is doped to match the doping concentration of the P-type regions, ensuring complete depletion within the super junction when the vertical JFET 40 is in the OFF state, effectively reducing leakage current. By optimizing the doping concentration gradient, the super junction structure minimizes conduction resistance, thereby improving the efficiency and stability of the vertical JFET 40.

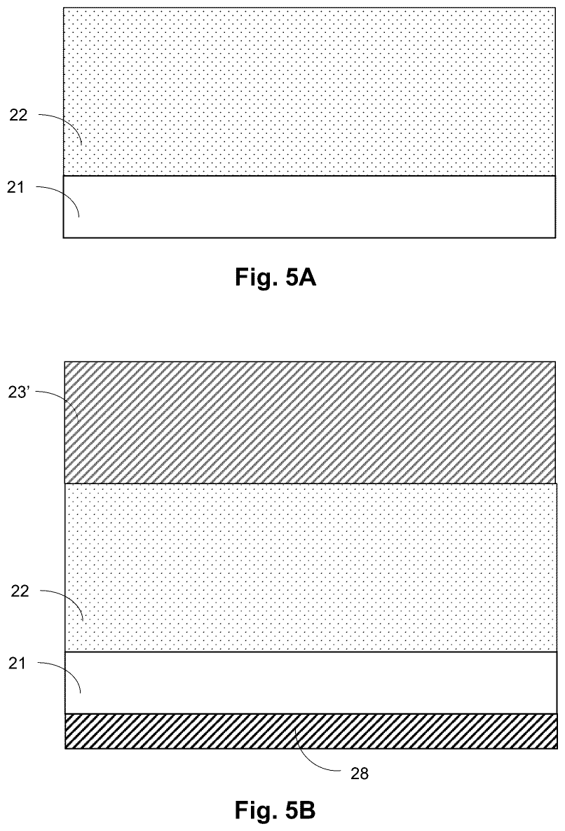

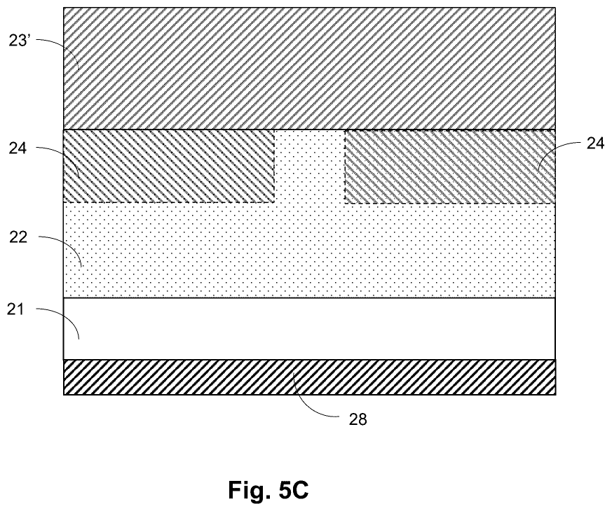

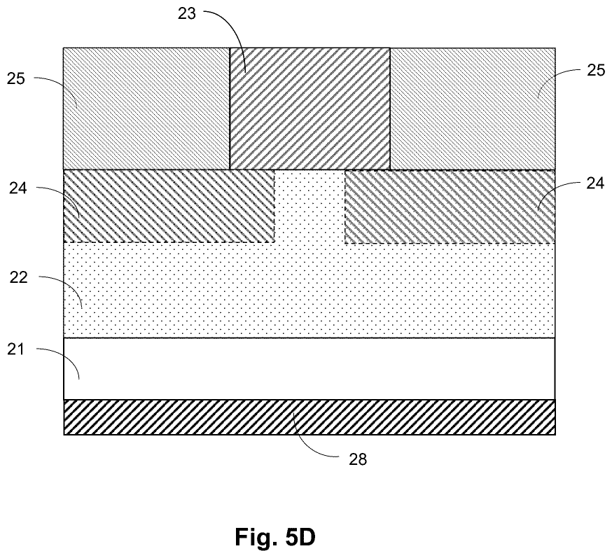

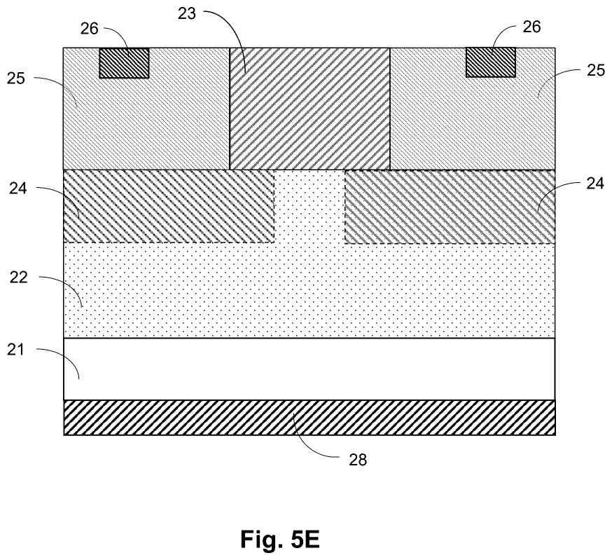

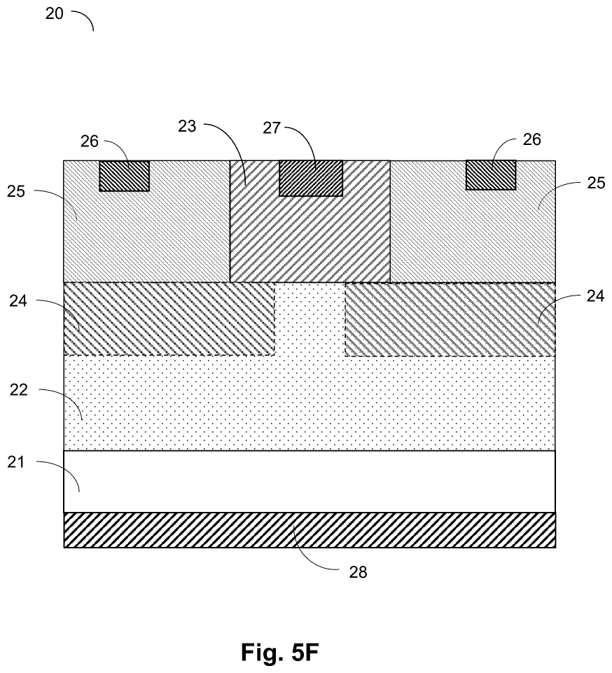

FIGS. 5A through 5F depict cross-sectional schematic diagrams illustrating the manufacturing method of the vertical JFET 20 according to an embodiment of the present invention. The method includes several steps, as detailed below.

As shown in FIG. 5A, an N+ type substrate 21 is provided as the manufacturing base. The substrate is made of semiconductor material, such as silicon (Si), silicon carbide (SiC), or gallium nitride (GaN). In a preferred embodiment, the N+ type substrate 21 is silicon carbide. An N-type bulk region 22 is formed on the N+ type substrate 21 using an epitaxial growth process. The N-type bulk region 22 is connected to the N+ type substrate 21.

Next, as illustrated in FIG. 5B, an extended drift region 23′ is formed on the N-type bulk region 22 to create the N-type drift region 23. The extended drift region 23′ may be formed using either an epitaxial growth process or an ion implantation process. The N-type drift region 23 serves as the primary current conduction channel for the vertical JFET 20, with its doping concentration and thickness determining the conduction resistance and breakdown voltage characteristics. If the extended drift region 23′ is formed via ion implantation, N-type impurities are implanted into the upper part of the N-type bulk region 22. As shown in FIG. 5B, an N+ type drain region 28 is formed beneath a portion of the N+ type substrate 21. The N+ type drain region 28 may also be formed via ion implantation, with N-type impurities implanted into the lower portion of the N+ type substrate 21.

As depicted in FIG. 5C, two P-type buried regions 24 are formed using ion implantation. These P-type buried regions 24 are positioned below the N-type drift region 23 on its left and right sides, separated horizontally without connection. The P-type buried regions 24 are spaced apart by a portion of the N-type bulk region 22, ensuring uniform electric field distribution and improving breakdown voltage performance.

Subsequently, as shown in FIG. 5D, two P-type base regions 25 are formed above the P-type buried regions 24 using another ion implantation process. These P-type base regions 25 are connected to the corresponding P-type buried regions 24, with a higher doping concentration to reduce the resistance between the P+ type gate regions 26 and the P-type buried regions 24.

As shown in FIG. 5E, two P+ type gate regions 26 are further formed within the P-type base regions 25 through ion implantation. The P+ type gate regions 26 are connected to the corresponding P-type base regions 25 and electrically linked to the P-type buried regions 24, forming a complete P-type region structure.

Finally, as illustrated in FIG. 5F, an N+ type source region 27 is embedded within the N-type drift region 23 using ion implantation. The N+ type source region 27 serves as the current input terminal, connecting to the N-type drift region 23 and the N-type bulk region 22, ensuring vertical current conduction to the N+ type substrate 21 and forming a complete vertical current path.

The overall structural design includes two independent and continuous P-type regions formed by the P-type buried regions 24 and the P-type base regions 25. These regions, in combination with the N-type drift region 23, may form a super junction structure. The super junction structure distributes the electric field uniformly, reduces conduction resistance, improves breakdown voltage performance, and significantly minimizes leakage current, thereby greatly enhancing the overall performance of the vertical JFET 20.

In one embodiment, the upper surface of the N-type drift region 23 and the upper surfaces of the two P-type base regions 25 are located entirely on the same horizontal plane at a vertical height. Two gates 26a (see FIG. 2A), which are electrically connected to the P+ type gate regions via ohmic contact, are also located entirely on this horizontal plane. The gate material may include titanium nitride (TiN), tantalum nitride (TaN), or aluminum (Al).

In one embodiment, the N-type drift region 23 is formed using an ion implantation process, with implanting elements such as nitrogen (N), phosphorus (P), arsenic (As), antimony (Sb), or bismuth (Bi).

In one embodiment, the P-type buried regions 24 and the P-type base regions 25 are respectively formed using corresponding ion implantation processes, with implanting elements such as boron (B), aluminum (Al), gallium (Ga), or indium (In).

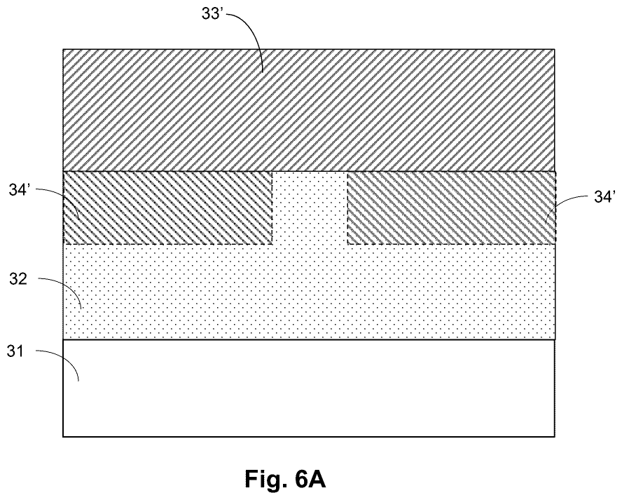

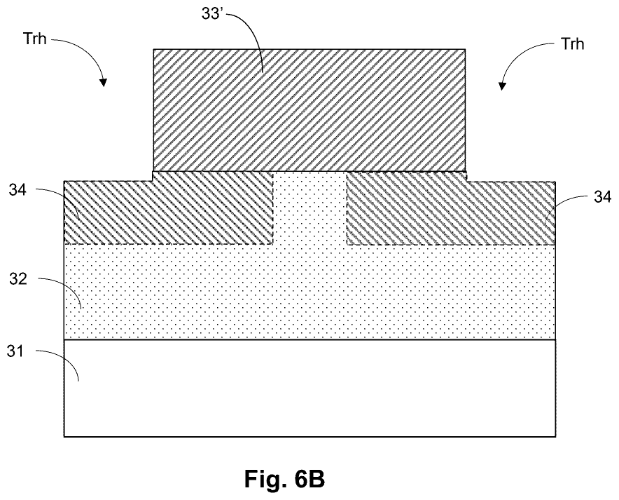

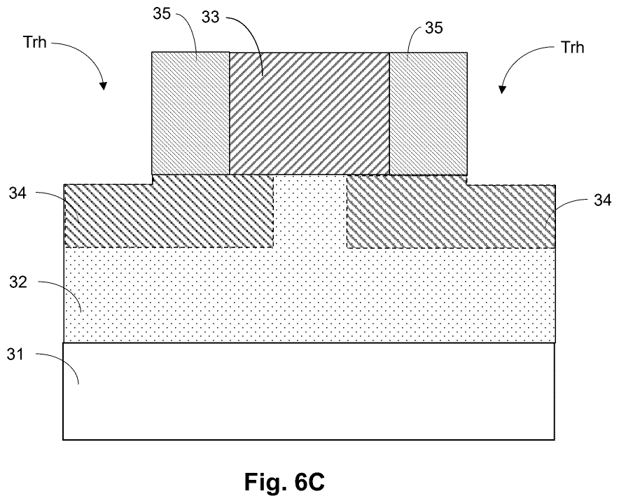

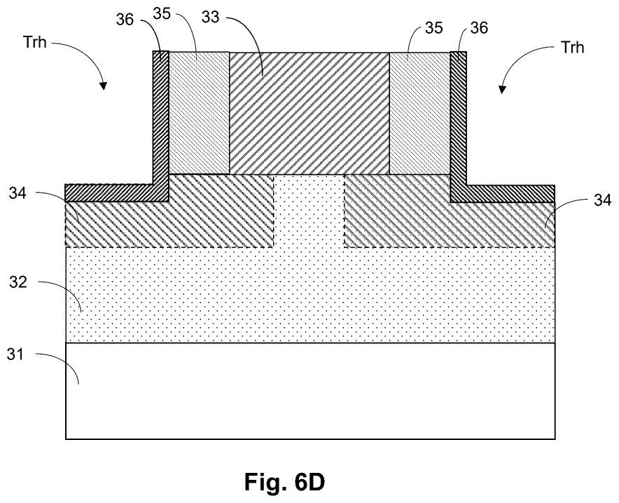

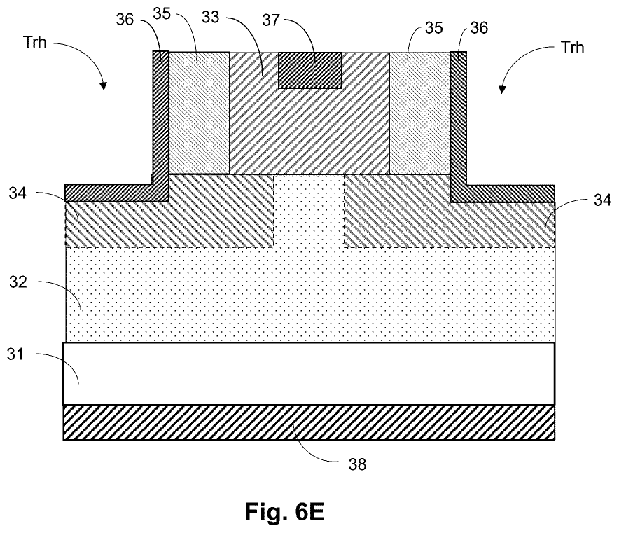

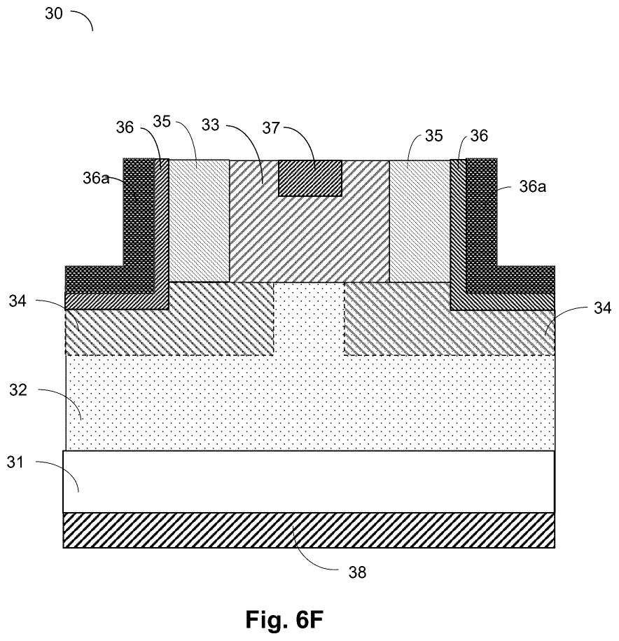

FIGS. 6A to 6F illustrate cross-sectional schematic diagrams of the manufacturing method for the vertical JFET 30 according to one embodiment of the present invention.

Referring to FIG. 6A, the manufacturing method begins with providing an N+ type substrate 31, composed of a semiconductor material such as silicon (Si), silicon carbide (SiC), or gallium nitride (GaN). An N-type bulk region 32 is formed above the N+ type substrate 31 using an epitaxial growth process. Additionally, an extended drift region 33′ is formed above the N-type bulk region 32 to further create an N-type drift region 33.

Subsequently, using an ion implantation process, two P-type implantation regions 34′ are formed beneath the extended drift region 33′ (later to become the N-type drift region 33). These P-type implantation regions 34′ serve as preliminary structures for forming the P-type buried regions 34.

Referring to FIG. 6B, an etching process is performed, where trenches Trh are etched downward from the upper surface of the extended drift region 33′ into the P-type implantation regions 34′. The inner walls of the trenches Trh come into contact with the P-type implantation regions, further defining the shape and position of the P-type buried regions 34.

As shown in FIG. 6C, a counter-doping ion implantation process is performed on the left and right sides of the extended drift region 33′ to compensate the doping and further form two P-type base regions 35. This step also finalizes the definition of the N-type drift region 33. The two P-type base regions 35 are located above the corresponding P-type buried regions 34 and electrically connected to them.

Referring to FIG. 6D, P-type impurities are implanted into the bottoms and inner sidewalls of the two trenches Trh within the P-type base regions 35 using an ion implantation process. This step forms the P+ type gate regions 36. Structurally, the P+ type gate regions 36 are connected to the P-type base regions 35 and electrically linked via the P-type base regions 35 or directly to the corresponding P-type buried regions 34.

As shown in FIG. 6E, an N+ type source region 37 is formed within the N-type drift region 33 using an ion implantation process. Simultaneously, a drain 38 is provided below the N+ type substrate 31, which may include metallic materials to enhance conductivity.

Finally, as depicted in FIG. 6F, a conductive material is deposited on the surface of the structure to form gates 36a, which are electrically connected to the P+ type gate regions 36. The gates 36a establish ohmic contact with the P+ type gate regions 36.

The upper surface of the N-type drift region 33 and the upper surfaces of the two P-type base regions 35 are located on the same horizontal plane at a vertical height. At least portions of the two P+ type gate regions 36 are positioned beneath this horizontal plane, along the bottoms and inner walls of the corresponding trenches Trh.

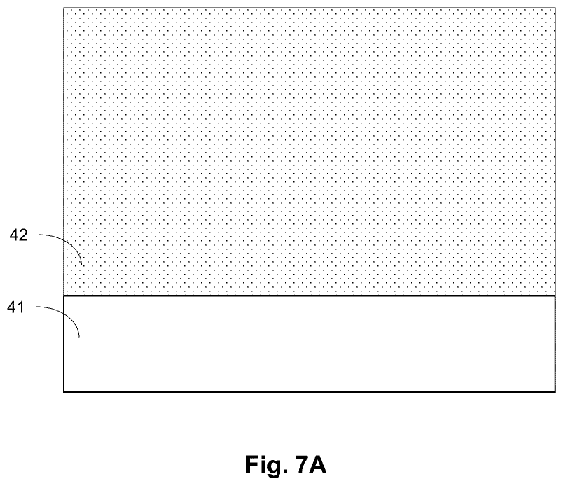

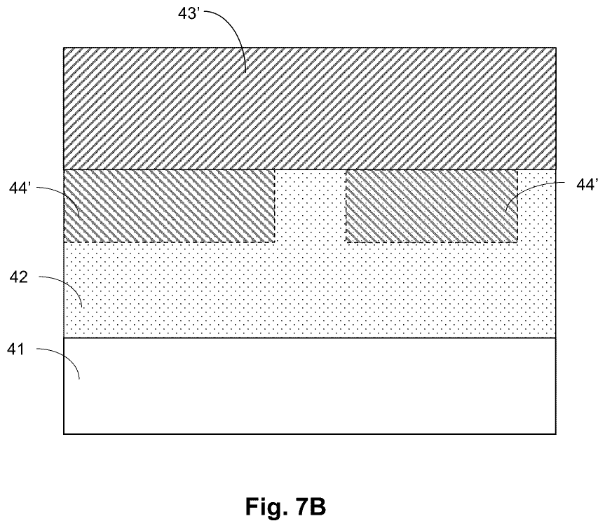

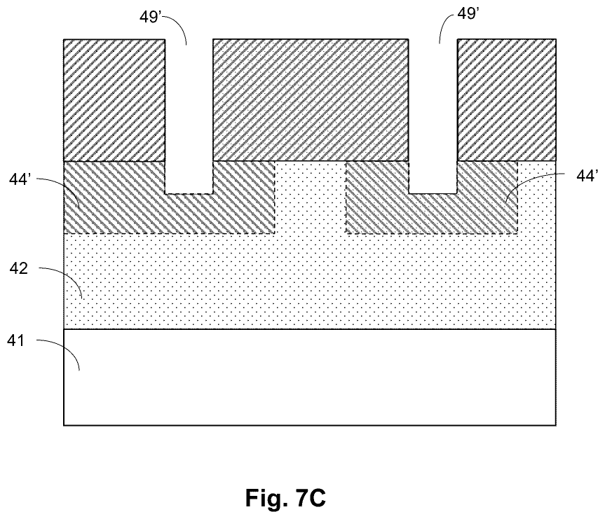

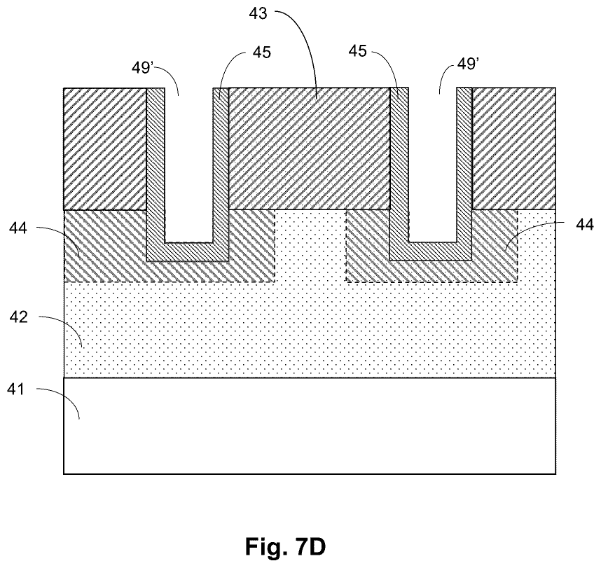

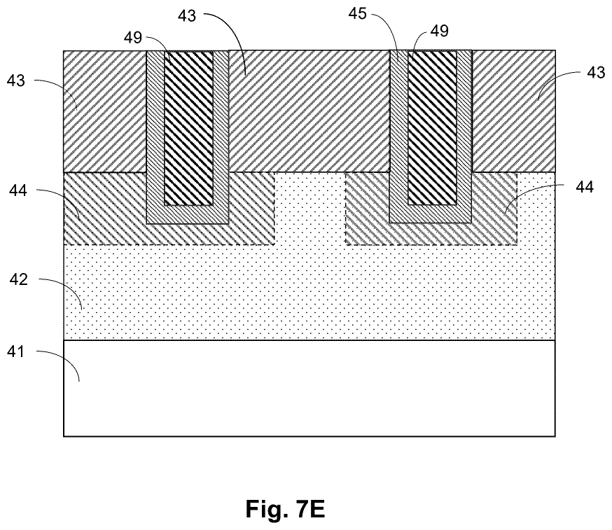

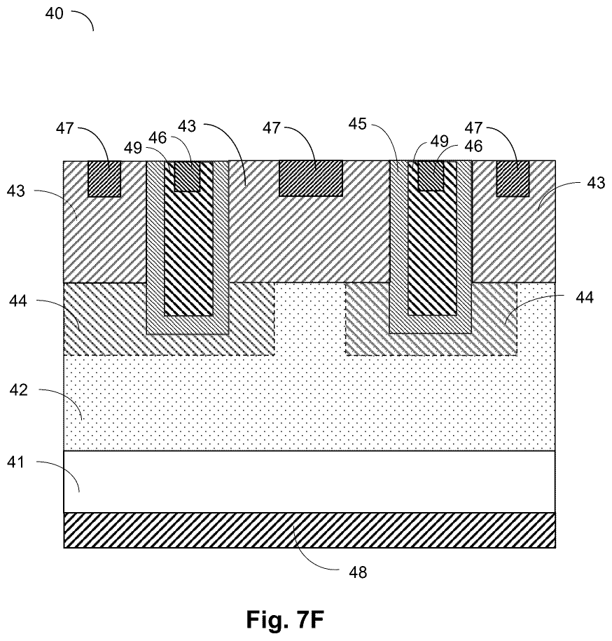

FIGS. 7A to 7F illustrate cross-sectional schematic diagrams of the manufacturing method for the vertical JFET 40 according to one embodiment of the present invention. The steps of this manufacturing method are detailed below with reference to the figures.

In FIG. 7A, an N+ type substrate 41, composed of a semiconductor material, is provided as the base for the vertical JFET 40. Subsequently, an N-type bulk region 42 is formed above the N+ type substrate 41. The N-type bulk region 42 can be grown using an epitaxial process, providing a layer connected to the N+ type substrate 41.

Moving to FIG. 7B, an extended drift region 43′ is formed above the N-type bulk region 42 to further create an N-type drift region 43. The extended drift region 43′ (later forming the N-type drift region 43) can be created through epitaxial growth or an ion implantation process. Beneath this extended drift region 43′, two P-type implantation regions 44′ are formed, which serve as the foundation for the subsequent P-type buried regions 44. This step ensures the vertical conductivity of the N-type drift region 43 and establishes the basis for forming a conduction channel.

As shown in FIG. 7C, an etching process is performed, where trenches 49′ are etched downward from the upper surface of the extended drift region 43′ into the previously formed P-type implantation regions 44′. These trenches 49′ define the structure for the subsequent formation of the P-type buried regions 44 and P-type base regions 45.

In FIG. 7D, P-type impurities are implanted into the bottom surfaces and inner sidewalls of the two trenches 49′ using an ion implantation process, thereby forming two P-type base regions 45. These regions are also connected to the corresponding P-type buried regions 44, further defining the N-type drift region 43. The formation of the P-type base regions 45 provides effective electric field control, enhancing the device's performance.

As shown in FIG. 7E, the trenches 49′ are filled with P-type pillars 49 to ensure structural integrity. These P-type pillars 49 are connected to the corresponding P-type base regions 45 and the P-type buried regions 44, forming a continuous structure. This design creates a super junction structure that improves the breakdown voltage and reduces leakage current.

Finally, in FIG. 7F, an N+ type source region 47 is formed within the N-type drift region 43, and P+ type gate regions 46 are formed within the P-type base regions 45. The N+ type source region 47 and the P+ type gate regions 46 are created using ion implantation processes. Metal ohmic contact techniques are then employed to form the source and gate electrodes, respectively. At this stage, the structure of the vertical JFET 40 is complete. The continuous P-type regions formed by the P-type buried regions 44 and the P-type base regions 45 provide an essential mechanism for reducing conduction resistance and improving the device's breakdown voltage characteristics.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, the frame may be arranged on a number of electronic components different from those shown in the figures, the order of placement of the frame and the sub-inductors may differ, or the shape of the frame may vary from that depicted in the figures. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A vertical junction field-effect transistor (JFET), comprising:
an N+ type substrate, made of a semiconductor material;
an N type bulk region, formed and connected above the N+ type substrate;
an N type drift region, formed and connected above the N type bulk region;
two P type buried regions, respectively formed beneath the N type drift region, spaced apart in a horizontal direction, unconnected to each other, and positioned at the left and right sides of the N type drift region, with a portion of the N type bulk region separating the two P type buried regions;
two P type base regions, respectively formed and connected above the corresponding two P type buried regions;
two P+ type gate regions, respectively connected to the corresponding two P type base regions and electrically connected to the P type buried regions via the corresponding two P type base regions; and
an N+ type source region, formed within the N type drift region;
wherein, when the vertical JFET is in a conductive state, a channel is formed exclusively in a vertical direction between the N+ type source region and the N+ type substrate through the N type drift region and the N type bulk region, enabling the conduction of current;
wherein the structure of the vertical JFET ensures that the channel is formed exclusively in the vertical direction, with the conduction current flowing vertically from the N+ type source region to the N+ type substrate;
wherein the two P type buried regions are respectively connected to the corresponding two P type base regions, forming two independent and continuous P type regions; and
wherein the two P type regions improve the conductive resistance, breakdown voltage, and leakage current characteristics of the vertical JFET.

2. The vertical JFET of claim 1, wherein the semiconductor material is silicon (Si), silicon carbide (SiC), or gallium nitride (GaN).

3. The vertical JFET of claim 1, wherein the N type drift region is formed using an epitaxial growth process or an ion implantation process.

4. The vertical JFET of claim 1, wherein the two P type buried regions extend horizontally relative to the corresponding two P type base regions in the following manners:
(a) extending beyond the sides of the corresponding two P type base regions to cover and connect to a portion of the lower surface of the N type drift region; or
(b) not extending beyond the sides of the corresponding two P type base regions and not covering the lower surface of the N type drift region.

5. The vertical JFET of claim 1, wherein the structure of the
vertical JFET includes:
(a) a planar structure, wherein the upper surface of the N type drift region and the upper surfaces of the two P type base regions lie on the same vertical height of a horizontal plane, and are respectively electrically connected to the two P+ type gate regions via ohmic contacts on two gates positioned entirely on the horizontal plane; or
(b) a trench structure, wherein the upper surface of the N type drift region and the upper surfaces of the two P type base regions lie on the same vertical height of a horizontal plane, with at least portions of the two P+ type gate regions located below the horizontal plane within the bottoms and sidewalls of two corresponding trenches, which extend downward from the horizontal plane into the interior of the two P type buried regions.

6. The vertical JFET of claim 1, wherein the two P type regions and the N type drift region form a super junction.

7. The vertical JFET of claim 1, wherein the two P type base regions have a higher doping concentration relative to the two P type buried regions to reduce the resistance between the two P+ type gate regions and the corresponding two P type buried regions, while the two P type buried regions have a relatively lower doping concentration to increase the breakdown voltage.

8. The vertical JFET of claim 1, further comprising two gates respectively connected to the corresponding two P+ type gate regions, wherein the two gates form ohmic contacts with the corresponding two P+ type gate regions, and the material of the two gates is titanium nitride (TiN), tantalum nitride (TaN), or aluminum (Al).

9. The vertical JFET of claim 1, wherein the N type drift region is formed using an ion implantation process with implant elements including nitrogen (N), phosphorus (P), arsenic (As), antimony (Sb), or bismuth (Bi).

10. The vertical JFET of claim 1, wherein the two P type buried regions and the two P type base regions are respectively formed using corresponding ion implantation processes with implant elements including boron (B), aluminum (Al), gallium (Ga), or indium (In).

11. A method for manufacturing a vertical junction field-effect transistor (JFET), comprising:
providing an N+ type substrate made of a semiconductor material;
forming an N type bulk region on and connected to the N+ type substrate;
forming an N type drift region on and connected to the N type bulk region;
forming two P type buried regions and two P type base regions;
forming two P+ type gate regions using an ion implantation process, respectively connected to the corresponding two P type base regions; and
forming an N+ type source region within the N type drift region using an ion implantation process;
wherein the two P type buried regions are formed beneath the N type drift region, spaced apart in a horizontal direction, unconnected to each other, and positioned at the left and right sides of the N type drift region, with a portion of the N type bulk region separating the two P type buried regions;
wherein the two P type base regions are respectively formed and connected above the corresponding two P type buried regions;
wherein the two P+ type gate regions are respectively electrically connected to the corresponding two P type buried regions via the corresponding two P type base regions;
wherein, when the vertical JFET is in a conductive state, a channel is formed exclusively in a vertical direction between the N+ type source region and the N+ type substrate through the N type drift region and the N type bulk region, enabling the conduction of current;
wherein the structure of the vertical JFET ensures that the channel is formed exclusively in the vertical direction, with the conduction current flowing vertically from the N+ type source region to the N+ type substrate; and
wherein the two P type buried regions are respectively connected to the corresponding two P type base regions, forming two independent and continuous P type regions used to improve the conductive resistance, breakdown voltage, and leakage current characteristics of the vertical JFET.

12. The manufacturing method of claim 11, wherein the structure of the vertical JFET includes a planar structure, wherein the formation steps of the two P type buried regions and the two P type base regions include:
(a) forming the two P type buried regions beneath the N type drift region using an ion implantation process; and
(b) forming the two P type base regions above the corresponding two P type buried regions using an ion implantation process;
wherein the N type bulk region is formed using an epitaxial growth process; and
wherein the upper surface of the N type drift region and the upper surfaces of the two P type base regions lie on the same vertical height of a horizontal plane, and are respectively electrically connected to the two P+ type gate regions via ohmic contacts on two gates positioned entirely on the horizontal plane.

13. The manufacturing method of claim 11, wherein the structure of the vertical JFET includes a trench structure;
wherein the steps of forming the two P type buried regions and the two P type base regions include:
forming two P type implanted regions beneath the N type drift region using an ion implantation process;
etching downward from a top surface to the interiors of the two P type implanted regions using an etching process to form two trenches and the two P type buried regions; and
forming the two P type base regions above the corresponding two P type buried regions using an ion implantation process;
wherein the step of forming the two P+ type gate regions respectively connected to the corresponding two P type base regions includes:
implanting P type impurities into the bottoms and interior sidewalls of the two trenches using an ion implantation process to form the two P+ type gate regions;
wherein the N type bulk region is formed using an epitaxial growth process;
wherein the upper surface of the N type drift region and the upper surfaces of the two P type base regions lie on the same vertical height of a horizontal plane, and at least portions of the two P+ type gate regions are respectively located below the horizontal plane within the corresponding two trench bottoms and interior sidewalls.

14. The manufacturing method of claim 11, wherein the structure of the vertical JFET includes a super junction structure;
wherein the steps of forming the two P type buried regions and the two P type base regions include:
forming two P type implanted regions beneath the N type drift region using an ion implantation process;
etching downward from a top surface to the interiors of the two P type implanted regions using an etching process to form two trenches and the two P type buried regions;
implanting P type impurities into the bottoms and interior sidewalls of the two trenches using an ion implantation process to form the two P type base regions; and
filling the two trenches with two P type columns;
wherein the two P type regions and the N type drift region form a super junction.

15. The manufacturing method of claim 11, wherein the semiconductor material is silicon (Si), silicon carbide (SiC), or gallium nitride (GaN).

16. The manufacturing method of claim 11, wherein the N type drift region is formed using an epitaxial growth process or an ion implantation process.

17. The manufacturing method of claim 11, wherein the two P type buried regions extend horizontally relative to the corresponding two P type base regions in the following manners:
(a) extending beyond the sides of the corresponding two P type base regions to cover and connect to a portion of the lower surface of the N type drift region; or
(b) not extending beyond the sides of the corresponding two P type base regions and not covering the lower surface of the N type drift region.

18. The manufacturing method of claim 11, wherein the doping concentration of the two P type base regions is higher than that of the two P type buried regions to reduce the resistance between the two P+ type gate regions and the corresponding two P type buried regions, while the doping concentration of the two P type buried regions is relatively lower to increase the breakdown voltage.

19. The manufacturing method of claim 11, further comprising two gates respectively connected to the corresponding two P+ type gate regions, wherein the two gates form ohmic contacts with the corresponding two P+ type gate regions, and the material of the two gates is titanium nitride (TiN), tantalum nitride (TaN), or aluminum (Al).

20. The manufacturing method of claim 11, wherein the N type drift region is formed using an ion implantation process with implantation elements including nitrogen (N), phosphorus (P), arsenic (As), antimony (Sb), or bismuth (Bi).

21. The manufacturing method of claim 11, wherein the P type buried regions and the P type base regions are respectively formed using corresponding ion implantation processes with implantation elements including boron (B), aluminum (Al), gallium (Ga), or indium (In).
